(19) United States
(12) Patent Application Publication
(10) Pub. No.: US 2011/0126896 A1
(43) Pub. Date: Jun. 2, 2011

(54) Photovoltaic Devices and Methods for Producing the Same

(75) Inventors: Rui-Ren Wang, Tu-Chen City (TW); Chie Gau, Tu-Chen City (TW); Cheng-Yung Kuo, Tu-Chen City (TW); Chen-Kai Hsu, Tu-Chen City (TW)

(73) Assignee: TAIWAN TEXTILE RESEARCH INSTITUTE, Tu-Chen City (TW)

(21) Appl. No.: 12/629,216

(22) Filed: Dec. 2, 2009

(51) Int. Cl. H01L 51/44; H01L 51/48

(52) U.S. Cl. 136/256; 438/82; 257/E51.012

(57) ABSTRACT

Disclosed herein are hybrid solar cells and methods for fabricating the same. In one aspect, the method is characterized in transferring nanowires from one substrate to another substrate. In another aspect, the method is characterized in having an organic active layer that is not made of [6,6]-phenyl-C61-butyric acid methyl ester (PCBM) and said organic active layer comprises nanowires embedded therein.

### BACKGROUND

1. Field of Invention

The present disclosure in general relates to a photovoltaic device and a method for fabricating the same.

2. Description of Related Art

Presently, silicon (Si) is the most commonly used material in the fabrication of photovoltaic cells, sometimes termed solar cells, which convert sunlight into electricity energy. Single and multiple-junction p-n solar cells have been constructed for such purpose. A typical process of fabricating a hybrid solar cell usually involves forming a layer of n-type material (e.g., silicon nanorods) on ITO substrate, followed by depositing a layer of p-type material (e.g., a thiophene polymer) thereon. However, growth of the n-type material layer has not been easy, further, cost of the p-type polymer material such as [6,6]-phenyl-C61-butyric acid methyl ester (PCBM) is relatively high, hence precludes its wide spread use in solar cells, particularly, the solar cells with large surface area.

There exists in this art a need of an improved method of fabricating a hybrid solar cell.

### SUMMARY

In view of the above, one objective of this disclosure aims to provide an improved hybrid solar cell and a method for producing the same. The improved hybrid solar cell is characterized in not having PCBM in its organic layer.

In the first aspect, the disclosure relates to a method of fabricating a hybrid solar cell. The method includes growing a plurality of n-type silicon nanowires on a first substrate; forming an organic layer on a second substrate, wherein the organic layer is characterized in not having PCBM; and thermal pressing the plurality of n-type silicon nanowires of the first substrate into the organic layer of the second substrate so that the plurality of n-type silicon nanowires are released from the first substrate and embedded within the organic layer of the second substrate; and forming an electrode on the organic layer, which contains therein the plurality of embedded thermal pressed n-type silicon nanowires.

In some embodiments, growing the plurality of n-type silicon nanowires includes depositing a layer of metal on a surface of the first substrate; heating the first substrate until the metal is melted into a liquid; saturating the melted metal liquid with silicon by contacting the melted metal liquid with a gas comprising silicon; growing the plurality of silicon nanowires on the surface of the first substrate; and doping the plurality of silicon nanowires with a dopant to form the plurality of n-type silicon nanowires on the first substrate.

In some embodiments, the n-type silicon nanowires thus grown on the first substrate are further treated with a hydrogen fluoride solution before being thermal pressed into the organic layer of the second substrate.

In some embodiments, the metal is any of Au, Al, Fe, or Ti. In one specific example, the metal is Au. In some embodiments, the metal layer has a thickness for about 8 nm.

In some embodiments, the melted metal liquid is brought in contact with a gas comprising silicon so as to saturate the melted metal liquid with silicon. In some examples, the gas comprising silicon is silane or a mixture of silane and nitrogen.

In some embodiments, the plurality of silicon nanowires are growing by low pressure chemical vapor deposition (LPCVD) at a pressure from about 200 mTorr to about 400 mTorr for about 10 min to 60 min.

In some embodiments, the first and second substrates are respectively made of a material selected from the group consisting of glass, plastic and silicon dioxide. In some examples, the first substrate is made of silicon and the second substrate is made of plastic or glass.

In some embodiments, the second substrate further comprises a layer of an indium tin oxide (ITO) disposed thereon; and a layer of poly (3,4-ethylenedioxythiophene) poly(styrenesulfonate) (PEDOT:PSS) disposed on the ITO layer.

In some embodiments, the organic layer is made of poly-(3-hexylthiophene) (P3HT) and does not comprise PCBM.

In some embodiments, a layer of electrode is deposited onto the organic layer comprising therein a plurality of embedded n-type silicon nanowires, which are thermal-pressed into the organic layer. In some examples, the electrode comprises aluminum.

In some embodiments, the hybrid solar cell is further annealed by exposing the electrode under UV light for a period for about 5 to 10 min. In one example, the electrode is exposed at UV light for about 8 min.

In a second aspect of this disclosure, a hybrid solar cell fabricated by the forgoing method is provided. The hybrid solar cell comprises therein embedded n-type silicon nanowires may exhibit a higher open voltage.

These and other features, aspects, and advantages of the present disclosure will become better understood with reference to the following description and appended claims.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings,

FIG. 1 is a flowchart illustrating steps in a method of forming a dense layer of nanowires on a substrate according to one embodiment of this disclosure;

FIG. 2 is a schematic diagram of a hybrid solar cell according to one embodiment of this disclosure;

FIG. 3 is a flowchart illustrating steps in a method of fabricating a hybrid solar cell according to one embodiment of this disclosure;

FIG. 4 is a schematic diagram of a first substrate with nanowires and a solar cell substrate according to one embodiment of the present disclosure;

FIG. 5 is a scanning electron microscopy (SEM) photograph showing gold particles deposited on a SiO₂ substrate in accordance with one embodiment of the disclosure;

FIG. 6 is a graph illustrating the correlation between the length of nanowires and the growth time in accordance with one embodiment of this disclosure;

FIGS. 7A and 7B are scanning electron micrographs at ×5,000 and ×3,000 magnification, respectively showing the top view of the n-type silicon nanowires grown on a Si substrate in accordance with one embodiment of the disclosure;

FIG. 8 is a graph illustrating short circuit current (mA/cm²), open circuit voltage (V) and fill factor for a solar cell having an organic layer of P3HT in accordance with one embodiment of the present disclosure; and

FIG. 9 is a graph illustrating short circuit current (mA/cm²), open circuit voltage (V) and fill factor for a solar cell having an organic layer of P3HT with embedded nanowires therein in accordance with one embodiment of the present disclosure.

### DETAIL DESCRIPTION OF ILLUSTRATED EMBODIMENTS

Reference will now be made in detail to the preferred embodiments of the disclosure, examples of which are illustrated in the accompanying drawings. Wherever possible, the same reference numbers are used in the drawings and the description to refer to the same or like parts.

Embodiments of the present disclosure are directed to a hybrid solar cell and a method for fabricating the same. The hybrid solar cell is characterized in having an organic layer that is not made of PCBM and comprises embedded silicon nanowires (NWs) therein to allow the hybrid solar cell to exhibit improved electronic properties such as a higher open circuit voltage.

### I. General Method For Forming Silicon Nanowires

As used herein, the term “nanowire” generally refers to any elongated conductive or semiconductive material that has homogeneous or heterogeneous properties.

It should be noted that although embodiments herein are pertaining to silicon nanowires, however, the techniques described herein are also applicable to nanowires produced from other materials, which include, but are not limited to, Ge, Sn, Se, Te, B, C, P, B—C, B—Si, Si—C, Si—Ge, Si—Sn, Ge—Sn, SiC, GeS, GeSe, GeTe, SnS, SnSe, SnTe, PbO, PbS, PbSe, PbTe, CuF, CuCl, CuBr, CuI, AgF, AgCl, AgBr, Agl, BeSiN₂, CaCN₂, ZnGeP₂, CdSnAs₂, ZnSnSb₂, CuGeP₃, CuSi₂P₃, Si₃N₄, Ge₃N₄, Al₂O₃, AI₂CO, and an appropriate combination of two or more such materials. The nanowires can be fabricated from essentially any convenient material as stated above or can be substantially crystalline, substantially monocrystalline, polycrystalline or amorphous.

In one preferred embodiment of this disclosure, nanowires are grown in a fairly controlled manner on a substrate. Such nanowires may be further doped into p- or n-type semiconductors so as to have carrier mobility levels comparable to bulk single crystal materials. In one specific example, nanowires produced by the preferred method described herein are doped into n-type semiconductors.

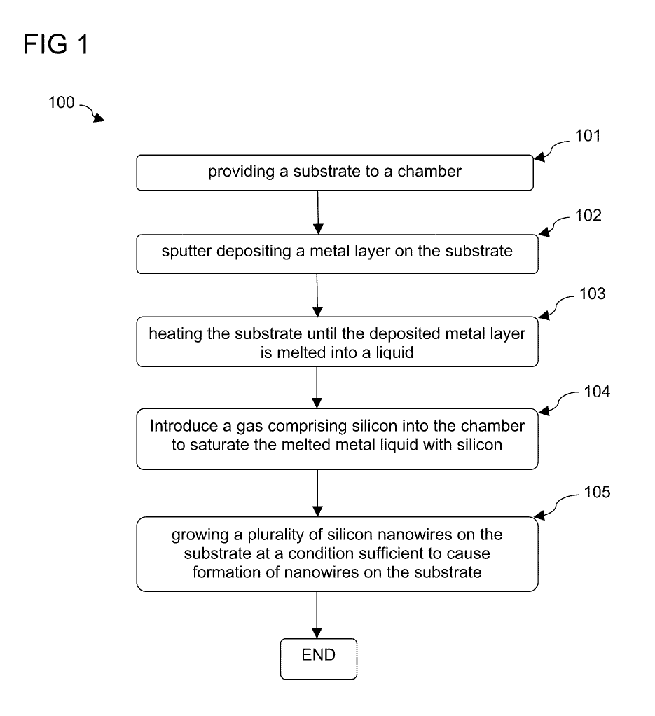

FIG. 1 is a flowchart illustrating steps in a method 100 according to one embodiment of this disclosure.

First, a substrate is provided in a low pressure chemical vapor deposition chamber (LPCVD) (step 101). The substrate may be any of glass, plastic or silicon dioxide, and may further comprise a dry oxide layer (e.g., SiO₂) coated thereon.

Metal particles are then deposited on the substrate through dip-coating or sputter deposition (step 102). Suitable metal particles are selected from the group consisting of Au, Al, Fe, and Ti. In one specific example, a layer of Au is sputter deposited onto the oxide layer until it reaches a thickness of at least 8 nm, such as 8, 9 or 10 nm.

After metal deposition, the substrate is then heated to a temperature until the deposited metal is melted into a liquid (step 103). In one example, the substrate in LPCVD chamber is heated to about 620° C. to melt the Au layer deposited thereon. The selection of the temperature depends on the selected metal intended to be deposited on the substrate. For example, if a titanium layer was sputtered deposited on the substrate, then the substrate needs to be heated to a temperature around 350° C. so as to melt the Ti layer.

After the metal is melted into a liquid, a gas comprising silicon is introduced into the LPCVD chamber to saturate the melted metal liquid with silicon (step 104). The gas comprising silicon may be silane or a mixture of silane and N₂. In one example, a mixture of silane and N₂ is supplied to the LPCVD chamber, with a flow rate of silane and N₂ being 100 sccm and 320 sccm, respectively.

A plurality of silicon nanowires are then grown on the substrate at a condition sufficient to cause formation of nanowires on the substrate (step 105). For example, the pressure in the LPCVD chamber may be kept at a level between about 200 mTorr and about 400 mTorr, such as about 200, 210, 220, 230, 240, 250, 260, 270, 280, 290, 300, 310, 320, 330, 340, 350, 360, 370, 380, 390, or 400 mTorr. The condition (e.g., temperature, pressure) may be maintained for about 10 min to 60 min, such as 10, 20, 30, 40, 50 or 60 min. In one example, the condition in the LPCVD chamber is maintained by keeping the pressure at about 330 mTorr, the temperature at about 620° C. for 20 min. As used herein, growth of nanowires refers to some substantially linear nanowires extending substantially perpendicular to the surface of the substrate. In general, the length of the nanowires thus grown is in proportion to the growth time. In this embodiment, the nanowires have an average length of about 2.75 μm, such as 2.5 μm, 2.75 μm or 3 μm.

The plurality of silicon nanowires thus obtained may be further doped with a dopant to form the plurality of doped silicon nanowires on the first substrate (step 106). The dopant may be selected from a group consisting of: a p-type dopant from Group III of the periodic table; an n-type dopant from Group V of the periodic table; a p-type dopant selected from a group consisting of: B, Al and In; an n-type dopant selected from a group consisting of: P, As and Sb; a p-type dopant from Group II of the periodic table; a p-type dopant selected from a group consisting of: Mg, Zn, Cd and Hg; a p-type dopant from Group IV of the periodic table; a p-type dopant selected from a group consisting of: C and Si; or an n-type dopant selected from a group consisting of: Si, Ge, Sn, S, Se and Te. Other now known or later developed dopant materials can be employed as well. In one specific example, the plurality of silicon nanowires are doped with phosphorous to form the plurality of n-type silicon nanowires on the substrate. Doping may be performed by any known procedures. For example, the dopant (e.g., P) may be reacted with Si nanowires at a temperature of 950° C. for about 1 hour in an inert environment or in the presence of nitrogen. A hydrogen fluoride solution (˜5%) is subsequently applied to the doped nanowires to remove excess phosphorous oxide from the outer surface of the phosphorous doped n-type silicone nanowires.

The nonowires thus obtained can have a variable diameter or can have a substantially uniform diameter, that is, a diameter that shows a variance less than 20%, (e.g., less than 10%, less than 5%, or less than 1%) over the region of greatest variability and over a linear dimension of at least 5 nm (e.g., at least 10 nm, at least 20 nm or at least 30 nm). A nanowire can be straight or can be curved or bent, over the entire length of its long axis or a portion thereof. Nanowires according to this disclosure are silicon nanowires, particularly, n-type silicon nanowires having a diameter of about 50 nm.

Once nanowires, particularly, n-type silicon nanowires, are formed on the surface of a substrate, a photovoltaic device such as a hybrid solar cell may be formed. Such device is described in further detail below.

### II. Method for Fabricating a Hybrid Solar Cell Including the Nanowires

Other embodiments of this disclosure are directed to an organic-inorganic hybrid solar cell and a method for producing the same. The hybrid solar cell described herein uses an organic material that is not PCBM as the active layer and comprises an ordered nanowire array within the organic active layer as a direct path to the electrode, and increasing the open circuit voltage of the solar cell.

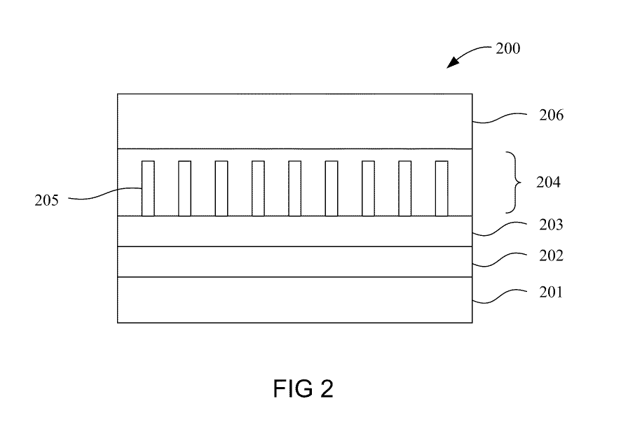

FIG. 2 is a schematic diagram of a hybrid solar cell 200 fabricated in accordance with one embodiment of the present disclosure. The hybrid solar cell 200 includes a substrate 201, a first conductive layer 202, a second conductive layer 203, an organic layer 204 characterized in not having PCBM and comprising a plurality of nanowires 205 embedded therein, and an electrode 206. The substrate 201 may be any of a material selected from the group consisting of glass, plastic, and silicon dioxide. In one example, the substrate is made of glass. In another example, the substrate is made of plastic. The first conductive layer 202 may comprise a transparent or translucent material such as indium tin oxide (ITO) to allow for the passage of the light. The second conductive layer 203 may comprise a conductive film made of poly (3,4-ethylenedioxythiophene) poly(styrenesulfonate) (PEDOT:PSS) to improve the transfer efficiency between donors and acceptors in the cell. The organic layer 204 is made of a semiconducting polymer that is not PCBM. Examples of the semiconducting polymer include polypyrrole, polythiophene, poly(3-alkylthiophene), polyaniline, polyfluorenes, polyaroamatic amines or poly(thienylene-vinylene). An example is poly-(3-hexylthiophene) (P3HT). In one specific example, the organic layer 204 is made of P3HT and further comprises a plurality of nanowires 205 embedded therein. In this example, P3HT retains its crystalline domains, and operates with embedded nanowires 205 to maintain high mobility in the cell. The electrode 206 is made of a metal selected from the group consisting of Ti, Pt, Cu, Al, TaN, Ca and Au.

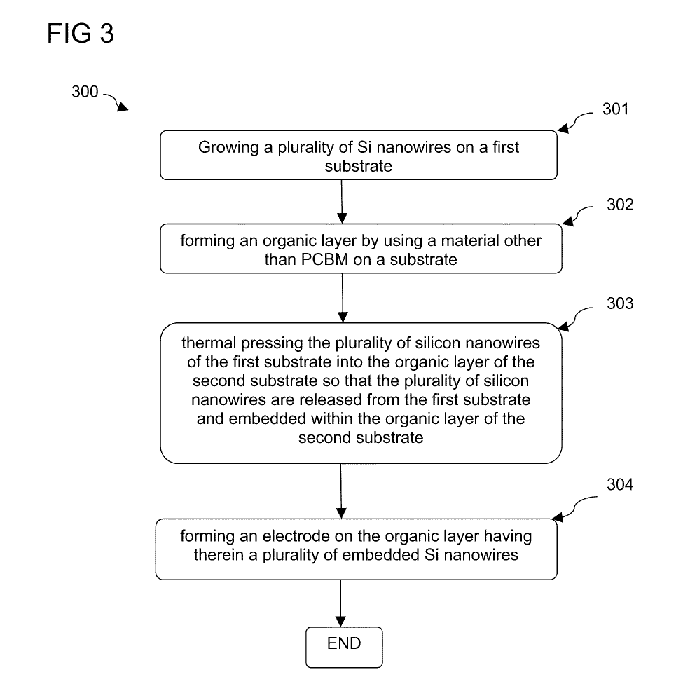

FIG. 3 is flowchart illustrating steps in a method 300 for fabricating the hybrid solar cell in according to one embodiment of this disclosure.

First, a plurality of Si nanowires are grown on a first substrate in according to the method 100 described above (step 301). The nanowires may be further doped with suitable dopant(s) to produced p- or n-type Si nanowires. In one example, the Si nanowires are doped with phosphorus to produce n-type Si nanowires. The first substrate may be made of glass, plastic or silicon dioxide, and may further comprise a dry oxide layer (e.g., SiO₂) coated thereon.

In a separate chamber on in the same chamber, an organic layer made from an organic material other than PCBM is formed on a second substrate (step 302). The second substrate may be any of glass, plastic or silicon dioxide, and further comprises in sequence from bottom to top: a first conductive layer and a second conductive layer. The first conductive layer may comprise a transparent or translucent material such as indium tin oxide (ITO) to allow for the passage of the light. The second conductive layer may comprise a conductive film made of poly (3,4-ethylenedioxythiophene) poly(styrenesulfonate) (PEDOT:PSS) to improve the transfer efficiency between donors and acceptors in the cell. The organic layer is made of a semiconducting polymer that is not PCBM. Examples of the semiconducting polymer include polypyrrole, polythiophene, poly(3-alkylthiophene), polyaniline, polyfluorenes, polyaroamatic amines or poly(thienylene-vinylene). In one example, the organic layer is made of poly-(3-hexylthiophene) (P3HT). The first conductive layer may be formed by sputtering and the second conductive layer may be formed by spin-coating.

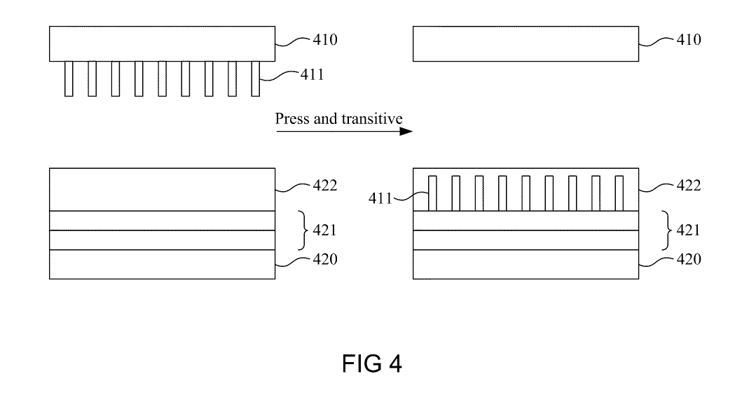

After the organic layer is formed, the nanowires formed on the first substrate are thermal-pressed into the organic layer in the second substrate so that the nanowires are released from the first substrate and embedded there within the organic layer of the second substrate (step 303). A schematic diagram illustrating the transfer process is depicted in FIG. 4. As depicted in FIG. 4, the first substrate 410 having nanowires 411 grown thereon is positioned above the second substrate 420 (e.g., the solar cell substrate having a conductive layer 421 and an organic layer 422 deposited thereon) with the organic layer 422 of the second substrate 420 facing upward, then a downward pressure may be applied form the back of the first substrate 410 to release the nonowires 411, the released nanowires 411 are embedded in the organic layer 422 of the second substrate 420. The temperature of the first and second substrates are kept at about 120° C. during the entire press and transfer operation.

After the nanowires are embedded in the organic layer, a layer of electrode is then formed on the organic layer by vapor deposition (step 304).

Suitable materials for the electrode include, but are not limited to, Ti, Pt, Cu, Al, Ca, TaN, Au and the combinations thereof. In one example, the electrode is formed by aluminum. Optionally, the electrode layer is annealed at about 150° C. for about 30 min to further reduce the sheet resistance. Some additional examples are provided below.

### EXAMPLES

### Example 1

### Formation of Phosphorous Doped Nanowires on a Silicon Substrate

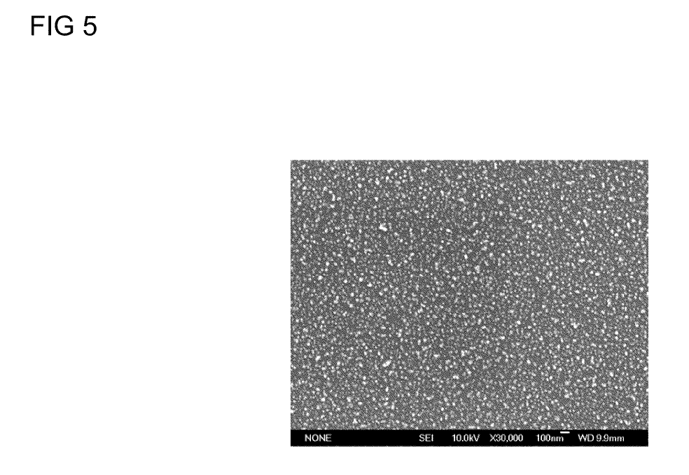

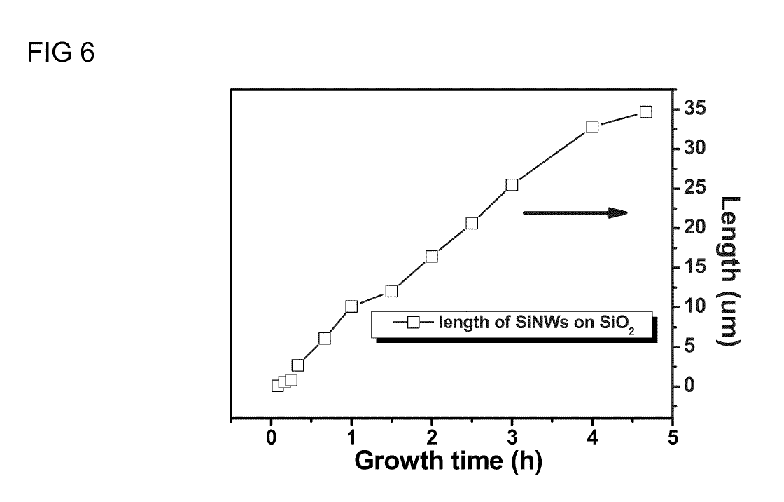

Arrays of phosphorous doped nanowires were synthesized on a silicon wafer in accordance with methods described above. Briefly, Si wafer was sonication-cleaned in acetone, iso-propanol and distilled water, respectively, and dried in a stream of gas. A thin layer of dried oxide, about 150 nm in thickness, was allowed to form on the surface of the cleaned Si wafer. Then, the substrate was dip-coated in a solution containing gold particles until a thin layer of gold (about 10 nm) was formed on the dried oxide layer. FIG. 5 is a scanning electron microscopy (SEM) photograph showing gold particles deposited on a Si substrate in accordance with this embodiment. The chamber pressure was maintained at about 333 mTorr and temperature at about 620° C. At this time, the gold layer was melted into a liquid under such high temperature. A mixture of silane (SiH₄) and nitrogen (N₂) was then introduced into the chamber at a flow rate of about 100 sccm and 320 sccm, respectively, so as to saturate the melted Au with Si. Nanowire arrays are then grown for about 0.2 to 2 hrs. This procedure reliably formed a dense layer of nanowires on the substrate surface. FIG. 6 is a graph illustrating the correlation between the length of nanowires and the growth time.

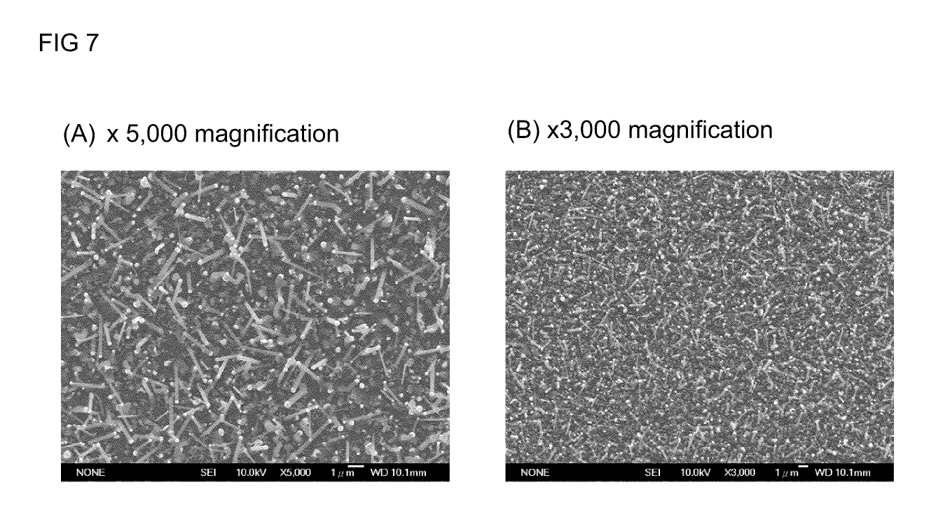

Phosphorous was then allowed to react with the as-made nanowires at 950° C. for 1 hr in the presence of N₂ so as to produce N-type Si nanowires. 5% of HF solution was then applied to remove excess phosphorous oxide formed on the outer surface of the nanowires. FIGS. 7A and 7B are scanning electron micrographs at ×5,000 and ×3,000 magnification, respectively showing the top view of the n-type silicon nanowires grown on a Si substrate in accordance with one embodiment of the disclosure.

### Example 2

### Fabrication of Hybrid Solar Cell

The as-made n-type Si nanowire film of Example 1 was used in this example for the construction of a hybrid solar cell. The solar cell was constructed by steps as follows. Briefly, an ITO glass substrate was sonication cleaned in acetone, iso-propanol and distilled water, respectively, and dried in a stream of gas. The clean substrate was further patterned by wet-etching with a diluted sulfuric acid, and the patterned ITO substrate was then allowed to react with a stream of O₂ to increase its surface hydrophilicity. A layer of PEDOT:PSS about 30 nm in thickness was subsequently spin coated on the treated and patterned ITO substrate at a speed of 4000 rpm for 60 sec, followed by firing at 150° C. for 30 min. The substrate was then allowed to cool down to room temperature. The substrate was then spin coated with a solution of P3HT (3 mg P3HT in 1 ml dichlorobenzene solution, 600 rpm for 60 sec) to form a P3HT active layer on the PEDOT:PSS layer.

The substrate having n-type Si nanowires formed thereon was place on top of the substrate of this example, with the side having n-type Si nanowires facing the P3HT layer, a slide (10 cm×10 cm×3 mm) was then placed on the back of the substrate of example 1 (i.e., the side without n-type Si nanowires) to apply pressure, so that n-type Si nanowires came off and got embedded in the underlying P3HT layer. Thermal pressing was performed at a temperature about 120° C. for about 10 min.

A layer of Al about 100 nm was then vapor deposited onto the P3HT layer, which contains embodded n-type Si nanowires. The substrate was then fired at 150° C. for about 30 min to reduce the sheet resistance.

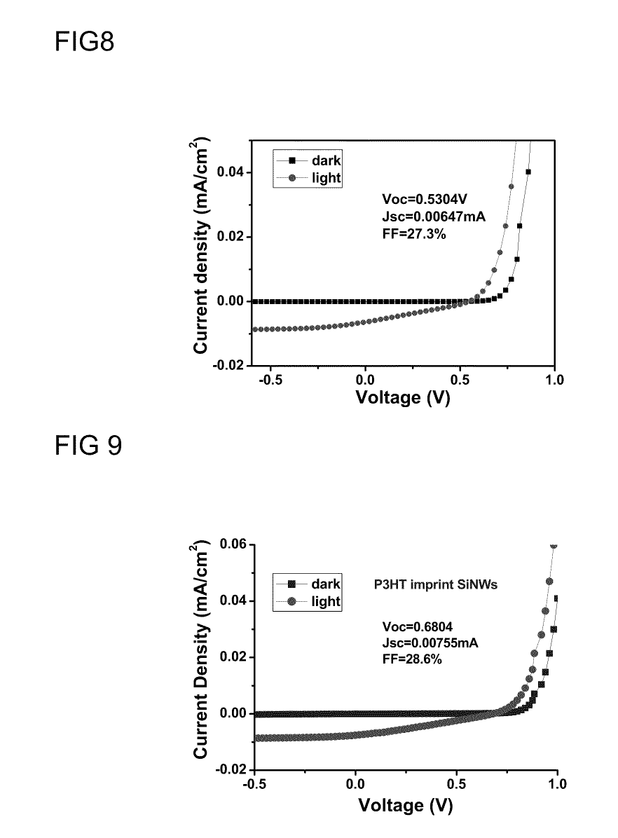

FIG. 8 is a graph illustrating short circuit current (mA/cm²), open circuit voltage (V) and fill factor for a solar cell having an organic layer of P3HT in accordance with one embodiment of the present disclosure. FIG. 9 is a graph illustrating short circuit current (mA/cm²), open circuit voltage (V) and fill factor for a solar cell with nanowires embedded within its organic layer of P3HT in accordance with one embodiment of the present disclosure. The solar cell with nanowires embedded therein has an open circuit voltage of 0.68 volt.

In summary, the present disclosure is directed to photovoltaic devices comprising an active layer that is not made of PCBM and comprises nanowires in the active layer to enhance open circuit voltage of the solar cell. Additionally, the present disclosure is also directed to methods of making and using such devices.

The foregoing description of various embodiments of the disclosure has been presented for purpose of illustration and description. It is not intended to be exhaustive or to limit the disclosure to the precise embodiments disclosed. Numerous modifications or variations are possible in light of the above teachings. The embodiments discussed were chosen and described to provide the best illustration of the principles of the disclosure and its practical application to thereby enable one of ordinary skill in the art to utilize the disclosure in various embodiments and with various modifications as are suited to the particular use contemplated. All such modifications and variations are within the scope of the disclosure as determined by the appended claims when interpreted in accordance with the breadth to which they are fairly, legally, and equitably entitled.

What is claimed is:

1. A method of fabricating a hybrid solar cell, comprising:
growing a plurality of n-type silicon nanowires on a first substrate;
forming an organic layer on a second substrate, wherein the organic layer is characterized in not having [6,6]-phenyl-C61-butyric acid methyl ester (PCBM); and
thermal pressing the plurality of n-type silicon nanowires of the first substrate into the organic layer of the second substrate so that the plurality of n-type silicon nanowires are released from the first substrate and embedded within the organic layer of the second substrate; and
forming an electrode on the organic layer, which contains therein the plurality of embedded thermal pressed n-type silicon nanowires.

2. The method of claim 1, further comprising the step of exposing the electrode at UV light for a period of about 5 to 10 min.

3. The method of claim 1, wherein growing the plurality of n-type silicon nanowires comprises steps of:
depositing a layer of metal on a surface of the first substrate;
heating the first substrate until the layer of metal thereon is melted into a liquid;
saturating the melted metal liquid with silicon by contacting the melted metal liquid with a gas comprising silicon;
growing the plurality of silicon nanowires on the surface of the first substrate; and
doping the plurality of silicon nanowires with a dopant to form the plurality of n-type silicon nanowires on the first substrate.

4. The method of claim 3, wherein the dopant is any of P, As or Sb.

5. The method of claim 3, further comprising treating the plurality of n-type silicon nanowires with a hydrogen fluoride solution before the plurality of n-type silicon nanowires on the first substrate are thermal pressed into the organic layer of the second substrate.

6. The method of claim 3, wherein the metal is any of Au, Al, Fe, or Ti.

7. The method of claim 6, wherein the metal is Au.

8. The method of claim 3, wherein the gas comprises silicon is silane or a mixture of silane and nitrogen.

9. The method of claim 3, wherein the layer of metal has a thickness of about 8 nm.

10. The method of claim 3, wherein the plurality of n-type silicon nanowires are grown by low pressure chemical vapor deposition (LPCVD) at a pressure between about 200 mTorr and about 400 mTorr for about 10 min to 60 min.

11. The method of claim 1, wherein the first and second substrates are respectively made of a material selected from the group consisting of glass, plastic and silicon dioxide.

12. The method of claim 11, wherein the first substrate is made of silicon and the second substrate is made of plastic or glass.

13. The method of claim 12, wherein the second substrate further comprising:
a layer of an indium tin oxide (ITO) disposed on the second substrate; and
a layer of PEDOT:PSS disposed on the ITO layer.

14. The method of claim 1, wherein the organic layer is made of poly-(3-hexylthiophene) (P3HT).

15. The method of claim 1, wherein the electrode comprises aluminum.

16. A hybrid solar cell, comprising:
a substrate;
a layer of indium tin oxide (ITO) disposed on the substrate;
a layer of PEDOT:PSS disposed on the ITO layer;
an organic layer formed from P3HT disposed on the ITO layer, wherein the organic layer is characterized in not having PCBM and comprises a plurality of n-type silicon nanowires being thermal pressed therein; and
an electrode disposed on the organic layer.

17. The hybrid solar cell of claim 16, wherein the substrate is made of a material selected from the group consisting of glass, plastic, and silicon dioxide.

18. The hybrid solar cell of claim 16, wherein the electrode comprises aluminum.
